(19) United States
(12) Patent Application Publication
(10) Pub. No.: US 2001/0027028 A1
(43) Pub. Date: Oct. 4, 2001

(54) Stock/transfer vessel for semiconductor substrate and method of manufacturing semiconductor device

(76) Inventor: Tatsuya Suzuki, Tokyo (JP)

Correspondence Address: HELFGOTT & KARAS, P.C., EMPIRE STATE BUILDING, 60TH FLOOR, NEW YORK, NY, 10118, US

(21) Appl. No.: 09/823,058

(22) Filed: Mar. 30, 2001

(30) Foreign Application Priority Data
Apr. 3, 2000 (JP) 100942/2000

(51) Int. Cl. H01L 21/31; H01L 21/469; B65D 85/30

(52) U.S. Cl. 438/762; 211/41.18; 206/711

(57) ABSTRACT

A semiconductor substrate stock/transfer vessel is an openable/closeable sealed vessel used in a semiconductor device manufacturing process and adapted to store or transfer a semiconductor substrate. The semiconductor substrate stock/transfer vessel incorporates at least one adsorbent capable of adsorbing an organic substance, and the adsorbent is mounted detachably.

### BACKGROUND OF THE INVENTION

1. Field of the Invention

The present invention relates to a stock/transfer vessel for a semiconductor substrate and a method of manufacturing a semiconductor device and, more particularly, to a stock/transfer vessel for a semiconductor device which is used in a semiconductor device manufacturing process and which can clean air in it, and a method of manufacturing a semiconductor device, which uses this stock/transfer vessel.

2. Description of the Prior Art

Conventionally, in a semiconductor device manufacturing process, a stock/transfer vessel which can stock and transfer a semiconductor substrate is used before the step of forming a gate oxide film, the step of forming a polysilicon film for a gate electrode, and the step of forming a contact hole in a semiconductor substrate such as a wafer or glass plate, so that an organic substance floating in the atmosphere of the clean room is prevented from attaching to the surface of a semiconductor substrate which awaits the operation of the respective steps.

FIG. 1 shows the schematic sectional structure of a conventional semiconductor substrate stock/transfer vessel 100, in which semiconductor substrates 101 are stored. The structure of this stock/transfer vessel and how to store semiconductor substrates will be described.

Referring to FIG. 1, reference numeral 101 denotes a semiconductor substrate; 102, a semiconductor substrate carrier; 103, a cover; 104, a retainer; 105, a seal member; and 106, a base plate, respectively.

As shown in FIG. 1, the semiconductor substrate stock/transfer vessel 100 is mainly constituted by the semiconductor substrate carrier 102 which can hold the semiconductor substrates 101, the base plate 106 on which the semiconductor substrate carrier 102 is placed, and the cover 103 arranged on the base plate 106 to cover the semiconductor substrate carrier 102.

As shown in FIG. 1, the plurality of semiconductor substrates 101 are loaded on the semiconductor substrate carrier 102 having a plurality of slots (not shown) each capable of holding one semiconductor substrate 101, and are stored in the stock/transfer vessel 100. The semiconductor substrate carrier 102 loaded with the semiconductor substrates 101 is placed on the base plate 106, and the cover 103 is arranged on the base plate 106 to cover the semiconductor substrate carrier 102. At this time, the semiconductor substrates 101 are fixed by the retainer 104 formed on the inner wall of the cover 103. The cover 103 and base plate 106 are fixed by a fixing member (not shown). The seal member 105 is provided between the base plate 106 and cover 103 so the stock/transfer vessel 100 is sealed completely. In the above manner, the semiconductor substrates 101 can be stored in the stock/transfer vessel 100 and isolated from the outer atmosphere.

To take out the semiconductor substrates 101 from the stock/transfer vessel 100, the fixing member which fixes the cover 103 and base plate 106 is removed, and the cover 103 is removed from the base plate 106. Then, the semiconductor substrate carrier 102 is taken out, and the semiconductor substrates 101 is taken out from the semiconductor substrate carrier 102.

In order to prevent an organic substance from attaching to the semiconductor substrates 101 stored in the stock/transfer vessel 100, generally, the respective members of the stock/transfer vessel 100 are made of materials that do not generate organic gases. However, when the semiconductor substrates 101 are to be stored in the stock/transfer vessel 100, a very small amount of organic substances floating in the atmosphere of the clean room and organic substances attaching to the lower surfaces of the semiconductor substrates 101 and regions of the upper surfaces of the semiconductor substrates 101 other than gate oxide regions flow into the stock/transfer vessel 100. As these organic substances are easily adsorbed onto the active regions of the semiconductor substrates 101, they may degrade the yield and reliability (e.g., the initial breakdown voltage of the gate oxide film or contact resistance) of the semiconductor devices to be manufactured.

### SUMMARY OF THE INVENTION

It is, therefore, an object of the present invention to provide a stock/transfer vessel for a semiconductor substrate, in which the above problems in the prior art are solved so the internal air can be cleaned. It is another object of the present invention to provide a method of manufacturing a semiconductor device which, in a semiconductor device manufacturing process, uses this stock/transfer vessel, so that the yield and reliability can be improved.

In order to achieve the above objects, according to the first aspect of the present invention, there is provided a semiconductor substrate stock/transfer vessel, which is an openable/closeable sealed vessel used in a semiconductor device manufacturing process and adapted to store or transfer a semiconductor substrate, wherein the vessel incorporates at least one adsorbent capable of adsorbing an organic substance, and the adsorbent is mounted detachably.

The semiconductor substrate stock/transfer vessel according to the present invention incorporates an adsorbent which can adsorb an organic substance. When a semiconductor substrate is to be stored in the stock/transfer vessel, even if an organic substance flows into the stock/transfer vessel, it can be adsorbed and removed by the adsorbent incorporated in the stock/transfer vessel, so the air in the stock/transfer vessel can be cleaned. Since the adsorbent is detachable, it can be exchanged with a new one before its organic substance adsorption amount is saturated. Therefore, the interior of the stock/transfer vessel can always be kept clean.

The stock/transfer vessel according to the present invention incorporates a semiconductor substrate carrier having a plurality of slots each capable of holding one semiconductor substrate, so that a plurality of semiconductor substrates can be stored while being held by the semiconductor substrate carrier.

In the stock/transfer vessel according to the present invention, the adsorbent is preferably a silicon wafer with a surface coated with an adsorbing agent such as active carbon or an ion-exchange resin. More preferably, the adsorbent is a silicon wafer with a surface having a Si—F bond.

The adsorbent is preferably a silicon wafer with a surface coated with an adsorbing agent such as active carbon or an ion-exchange resin, or a silicon wafer with a surface having a Si—F bond. When the adsorbent has this structure, it can be mounted in an empty slot of the semiconductor substrate carrier.

The adsorbing agent, e.g., active carbon or the ion-exchange resin, which coats the surface of a silicon wafer has certain characteristics: it has a polar bond such as a C═O bond or C—O bond, it can selectively adsorb an organic substance having a polar bond, e.g., dioctyl phthalate (to be referred to as DOP hereinafter) or dibutyl phthalate (to be referred to as DBP hereinafter), and it does not desorb an organic substance it has adsorbed once. The silicon wafer with a surface having a Si—F bond also has certain characteristics: it can selectively adsorb an organic substance having a polar bond, e.g., DOP or DBP, and at room temperature it does not desorb an organic substance it has adsorbed once, since the Si—F bond has a polarity.

In particular, the silicon wafer with a surface having a Si—F bond can firmly adsorb an organic substance having a polar bond, e.g., DOP or DBP, since the polarity of the Si—F bond is large. This silicon wafer thus has a high adsorbing performance and is effective as an adsorbent. The silicon wafer with a surface having a Si—F bond is also excellent in that it can be fabricated by treating a silicon wafer, used in the manufacture of a semiconductor device, with hydrofluoric acid, without rinsing with pure water, so it can be easily supplied in a semiconductor device manufacturing line.

Also, the adsorbent can be made of active carbon or an ion-exchange resin. In this case as well, the air in the stock/transfer vessel can be cleaned.

In the semiconductor device manufacturing process, a semiconductor substrate which awaits operation is stored in the above semiconductor substrate stock/transfer vessel according to the present invention, so that an organic substance can be prevented from attaching to the surface of the semiconductor substrate in stock. Therefore, a semiconductor device manufacturing method which can improve the yield and reliability can be provided.

In particular, in the semiconductor device manufacturing method, a semiconductor substrate which awaits operation such as the step of forming a gate oxide film, the step of forming a polysilicon film, and the step of forming a contact hole is preferably stored in the stock/transfer vessel of the present invention. When the semiconductor substrate is stored in the stock/transfer vessel of the present invention during an operation wait time between these steps, an organic substance can be prevented from attaching to the surface of the semiconductor substrate in stock, and the yield and reliability can be improved.

The above and many other objects, features and advantages of the present invention will become manifest to those skilled in the art upon making reference to the following detailed description and accompanying drawings in which preferred embodiments incorporating the principle of the present invention are shown by way of illustrative examples.

### BRIEF DESCRIPTION OF THE DRAWINGS

FIG. 1 is a schematic longitudinal sectional view showing a state wherein a plurality of semiconductor substrates are stored in a conventional semiconductor substrate stock/transfer vessel;

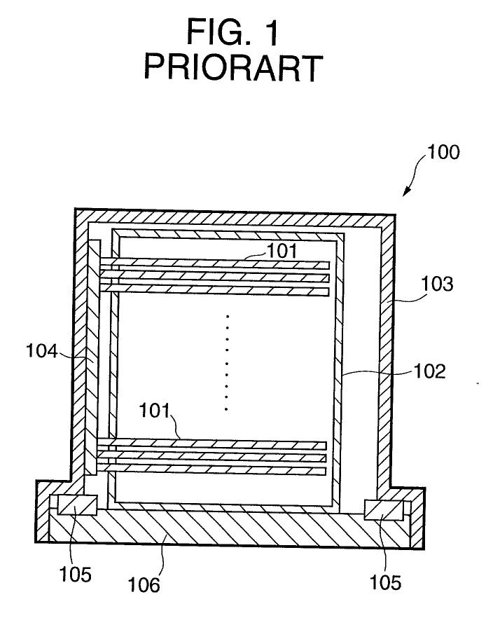

FIGS. 2A and 2B are a schematic vertical sectional view and a schematic horizontal sectional view, respectively, showing a state wherein a plurality of semiconductor substrates are stored in a semiconductor substrate stock/transfer vessel according to the first embodiment of the present invention;

FIG. 3 is a schematic longitudinal sectional view showing a state wherein a plurality of semiconductor substrates are stored in a semiconductor substrate stock/transfer vessel according to the second embodiment of the present invention;

FIG. 4 is a flow chart showing a method of manufacturing a semiconductor device according to the present invention in the order of its steps; and

FIGS. 5A and 5B are graphs showing the histograms of the initial breakdown voltages of the gate oxide films of respective chips, in which FIG. 5A is a graph concerning chips manufactured according to the present invention, and FIG. 5B is a graph concerning chips manufactured according to the conventional manufacturing method for the purpose of comparison.

### DETAILED DESCRIPTION OF PREFERRED EMBODIMENTS

Several preferred embodiments of the present invention will be described in detail with reference to the accompanying drawings.

First Embodiment

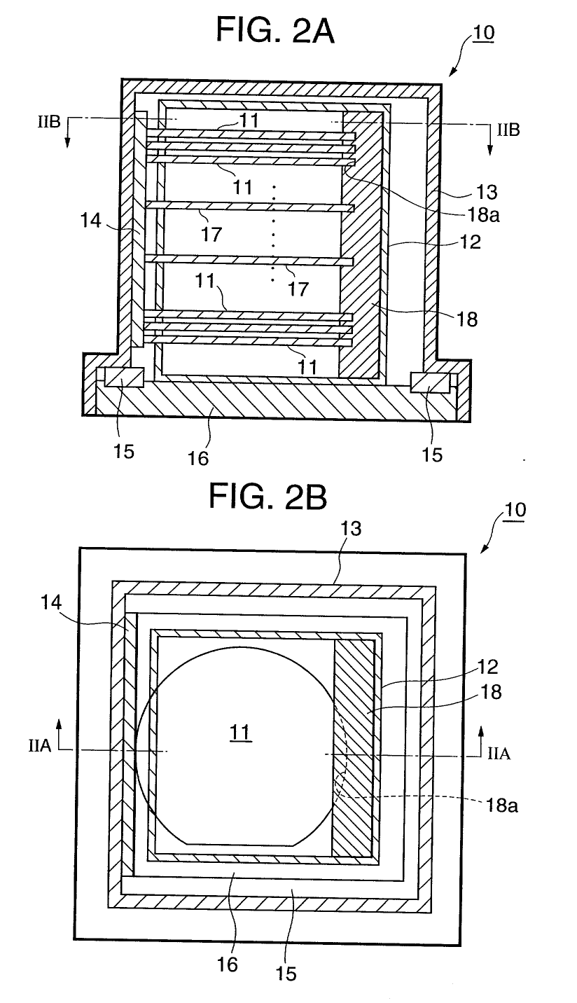

FIGS. 2A and 2B show the schematic vertical sectional structure of a semiconductor substrate stock/transfer vessel 1 according to the first embodiment of the present invention, in which semiconductor substrates 11 are stored. The structure of this stock/transfer vessel and how to store semiconductor substrates will be described. Although the vessel or the like shown in FIGS. 2A and 2B has a rectangular shape for the sake of convenience, it is not limited to this shape, and a cylindrical vessel or vessels with other shapes can be suitably used.

Referring to FIGS. 2A and 2B, reference numerals 11 denote semiconductor substrates (wafers or the like); 12, a semiconductor substrate carrier; 13, a cover; 14, a retainer; 15, a seal member; 16, a base plate; and 17, adsorbents, respectively. A slot member 18 with a plurality of slots 18a in each of which part of one semiconductor substrate 11 is inserted is mounted on the semiconductor substrate carrier 12.

As shown in FIGS. 2A and 2B, the semiconductor substrate stock/transfer vessel 10 is mainly constituted by the semiconductor substrate carrier 12 which can hold the semiconductor substrates 11, the base plate 16 on which the semiconductor substrate carrier 12 is placed, and the cover 13 arranged on the base plate 16 to cover the semiconductor substrate carrier 12.

FIG. 2A is a longitudinal sectional view taken along the line IIA-IIA of FIG. 2B, and FIG. 2B is a horizontal sectional view taken along the line IIB-IIB of FIG. 2A.

As shown in FIGS. 2A and 2B, the plurality of semiconductor substrates 11 formed of wafers or glass plates are held by the semiconductor substrate carrier 12 with the slot member 18 having the plurality of slots 18a, each capable of holding one semiconductor substrate 11, at appropriate portions, and are stored in the stock/transfer vessel 10. In the first embodiment, as shown in FIG. 2A, one or the plurality of detachable adsorbents 17 capable of adsorbing an organic substance are mounted in the empty slot(s) of the semiconductor substrate carrier 12. The semiconductor substrate carrier 12 loaded with the semiconductor substrates 11 is placed on the base plate 16, and the cover 13 is arranged on the base plate 16 to cover the semiconductor substrate carrier 12. At this time, the semiconductor substrates 11 and adsorbents 17 are fixed by the retainer 14 formed on the inner wall of the cover 13. The cover 13 and base plate 16 are fixed by a fixing member (not shown). The seal member 15 is provided between the base plate 16 and cover 13 so the stock/transfer vessel 10 is sealed completely. In the above manner, the semiconductor substrates 11 can be stored in the stock/transfer vessel 10 and isolated from the outer atmosphere.

To take out the semiconductor substrates 11 from the stock/transfer vessel 10, the fixing member which fixes the cover 13 and base plate 16 is removed, and the cover 13 is removed from the base plate 16. Then, the semiconductor substrate carrier 12 is taken out, and the semiconductor substrates 11 is taken out from the semiconductor substrate carrier 12.

When the semiconductor substrates 11 are to be stored in the stock/transfer vessel 10, a very small amount of organic substance floating in the atmosphere of the clean room and organic substances attaching to the lower surfaces of the semiconductor substrates 11 and regions of the upper surfaces of the semiconductor substrates 11 other than gate oxide regions flow into the stock/transfer vessel 10. The organic substances flowing into the stock/transfer vessel 10 are adsorbed by the adsorbents 17 incorporated in the stock/transfer vessel 10 (in the semiconductor substrate carrier 12) and are thus removed. The adsorbents 17 are detached before their organic substance adsorption amounts are saturated, and are exchanged with new adsorbents 17.

The structures of the adsorbent 17 according to the first embodiment will be described in detail. The adsorbent 17 is formed of a silicon wafer with a surface coated with an adsorbing agent such as active carbon or an ion-exchange resin, or a silicon wafer with a surface having a Si—F bond.

The adsorbing agent, e.g., active carbon or the ion-exchange resin, which coats the silicon wafer has certain characteristics: it has a polar bond such as a C═O bond or C—O bond, it can selectively adsorb an organic substance having a polar bond, e.g., dioctyl phthalate (to be referred to as DOP hereinafter) or dibutyl phthalate (to be referred to as DBP hereinafter), and it does not desorb an organic substance it has adsorbed. The silicon wafer with a surface having a Si—F bond also has certain characteristics: it can selectively adsorb an organic substance having a polar bond, e.g., DPO or DBP, and at room temperature it does not desorb an organic substance it has adsorbed once, since the Si—F bond has a polarity.

In particular, the silicon wafer with a surface having a Si—F bond can firmly adsorb an organic substance having a polar bond, e.g., DOP or DBP, since the polarity of the Si—F bond is large. This silicon wafer thus has a high adsorbing performance and is effective as an adsorbent 17. The silicon wafer with a surface having a Si—F bond is also excellent in that it can be fabricated by treating a silicon wafer, used in the manufacture of a semiconductor device, with hydrofluoric acid, without rinsing with pure water, so it can be easily supplied in a semiconductor device manufacturing line.

The semiconductor substrate stock/transfer vessel 10 according to the first embodiment incorporates the adsorbents 17 which can adsorb an organic substance. When the semiconductor substrates 11 are to be stored in the stock/transfer vessel 10, even if an organic substance flows into the stock/transfer vessel 10, it can be adsorbed and removed by the adsorbents 17 incorporated in the stock/transfer vessel 10, so the air in the stock/transfer vessel 10 can be cleaned.

Second Embodiment

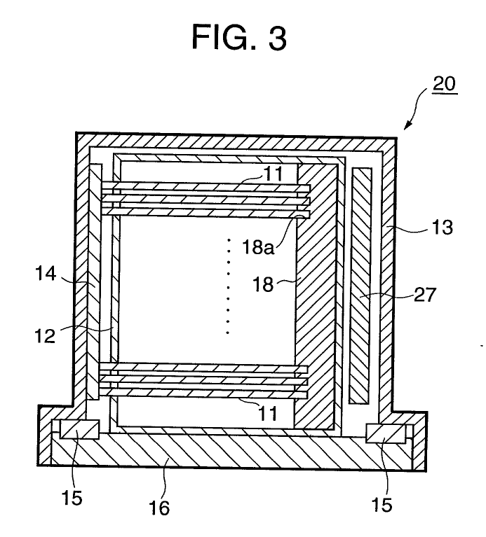

FIG. 3 shows the schematic sectional structure of a semiconductor substrate stock/transfer vessel 20 according to the second embodiment of the present invention, in which semiconductor substrates 11 are stored. The structure of this stock/transfer vessel and how to store semiconductor substrates will be described.

Referring to FIG. 3, the same constituent elements as those of the stock/transfer vessel 10 according to the first embodiment are denoted by the same reference numerals as in the first embodiment.

As shown in FIG. 3, the semiconductor substrate stock/transfer vessel 10 is mainly constituted by a semiconductor substrate carrier 12 which can hold the semiconductor substrates 11, a base plate 16 on which the semiconductor substrate carrier 12 is placed, and a cover 13 arranged on the base plate 16 to cover the semiconductor substrate carrier 12. The schematic shape of the stock/transfer vessel 20 is substantially the same as that of the first embodiment shown in FIGS. 2A and 2B.

In the second embodiment, one or a plurality of detachable adsorbents 27 capable of adsorbing an organic substance are mounted in the space defined between the inner wall of the stock/transfer vessel 20 and the outer wall of the semiconductor substrate carrier 12.

As shown in FIG. 3, the plurality of semiconductor substrates 11 are held by the semiconductor substrate carrier 12 with a slot member 18 having a plurality of slots 18a, each capable of holding one semiconductor substrate 11, at appropriate portions, and are stored in the stock/transfer vessel 10. The semiconductor substrate carrier 12 which holds the semiconductor substrates 11 is placed on the base plate 16, and the cover 13 is arranged on the base plate 16 to cover the semiconductor substrate carrier 12. At this time, the semiconductor substrates 11 are fixed by a retainer 14 formed on the inner wall of the cover 13. The cover 13 and base plate 16 are fixed by a fixing member (not shown). A seal member 15 is provided between the base plate 16 and cover 13 so the stock/transfer vessel 10 is sealed completely. In the above manner, the semiconductor substrates 11 can be stored in the stock/transfer vessel 10 and isolated from the outer atmosphere.

To take out the semiconductor substrates 11 from the stock/transfer vessel 10, the fixing member which fixes the cover 13 and base plate 16 is removed, and the cover 13 is removed from the base plate 16. Then, the semiconductor substrate carrier 12 is taken out, and the semiconductor substrates 11 is taken out from the semiconductor substrate carrier 12.

When the semiconductor substrates 11 are to be stored in the stock/transfer vessel 20, a very small amount of organic substance floating in the atmosphere of the clean room and organic substances attaching to the lower surfaces of the semiconductor substrates 11 and the like flow into the stock/transfer vessel 20. The organic substances flowing into the stock/transfer vessel 20 are adsorbed by the adsorbents 27 and are thus removed. The adsorbents 27 are detached before their organic substance adsorption amounts are saturated, and are exchanged with new adsorbents 27.

The structures of the adsorbent 27 will be described in detail. The adsorbent 27 is made of active carbon, an ion-exchange resin, or the like. The adsorbent 27 has certain characteristics: it has a polar bond such as a C═O bond or C—O bond, it can selectively adsorb an organic substance having a polar bond, e.g., DOP or DBP, and at room temperature it does not desorb an organic substance it has adsorbed once.

The semiconductor substrate stock/transfer vessel 20 according to the second embodiment incorporates the adsorbents 27 which can adsorb an organic substance. When the semiconductor substrates 11 are to be stored in the stock/transfer vessel 20, even if an organic substance flows into the stock/transfer vessel 20, it can be adsorbed and removed by the adsorbents 27 incorporated in the stock/transfer vessel 20, so the air in the stock/transfer vessel 20 can be cleaned.

Third Embodiment

A semiconductor device manufacturing method using either one of the stock/transfer vessels 10 and 20 respectively according to the first and second embodiments will be described.

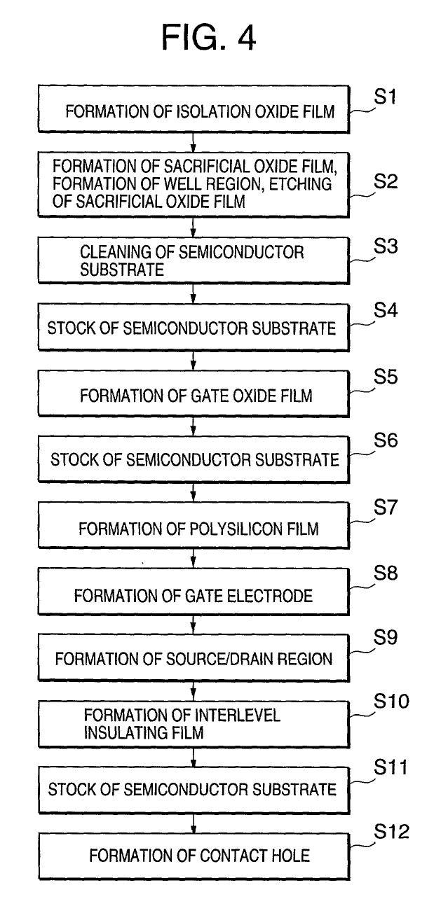

FIG. 4 is a flow chart showing a method of manufacturing a semiconductor device according to the present invention. Description will be made with reference to FIG. 4. FIG. 4 is a flow chart showing steps until contact hole formation in a semiconductor device manufacturing process. Steps after contact hole formation are identical to the known ones, and a detailed description thereof will be omitted.

First, an isolation oxide film is formed on the semiconductor substrate 11 formed of a wafer or glass plate (step S1). Subsequently, a sacrificial oxide film is formed on the semiconductor substrate 11. An impurity is implanted in the semiconductor substrate 11 to form a well region, and then the sacrificial oxide film is removed by etching (step S2). After that, the semiconductor substrate 11 is cleaned (step S3). At this time, SC1 cleaning for removing particles and SC2 cleaning for removing metals and the like are performed.

After the semiconductor substrate 11 is cleaned, it is stored in the stock/transfer vessel 10 or 20 described above (step S4) during an operation await time until formation of a gate oxide film on the semiconductor substrate 11 is started.

After that, as soon as the gate oxidation furnace becomes vacant, the semiconductor substrate 11 is taken out from the stock/transfer vessel 10 or 20 and is set in the gate oxidation furnace, and a gate oxide film is formed on it (step S5).

After the gate oxide film is formed on the semiconductor substrate 11, the semiconductor substrate 11 is stored in the stock/transfer vessel 10 or 20 during an operation wait time until polysilicon film for gate electrode formation is formed on the semiconductor substrate 11 (step S6). As soon as the polysilicon film formation furnace becomes vacant, the semiconductor substrate 11 is taken out from the stock/transfer vessel 10 or 20 and is set in the polysilicon film formation furnace, and a polysilicon film is formed on it (step S7)

After the polysilicon film is formed on the semiconductor substrate 11, it is patterned, thereby forming a gate electrode (step S8). After that, a source/drain region is formed on the semiconductor substrate 11 (step S9), and then an interlevel insulating film is formed on it (step S10).

After the interlevel insulating film is formed on the semiconductor substrate 11, the semiconductor substrate 11 is stored in the stock/transfer vessel 10 or 20 described above in an operation wait time until contact hole formation (step S11). As soon as the contact hole formation unit becomes vacant, the semiconductor substrate 11 is taken out from the stock/transfer vessel 10 or 20, and a contact hole is formed in it (step S12).

According to the third embodiment, in a semiconductor device manufacturing process, a semiconductor substrate which awaits operation is stored in the semiconductor substrate stock/transfer vessel according to the present invention, so that an organic substance can be prevented from attaching to the surface of the semiconductor substrate in stock. Therefore, a semiconductor device manufacturing method which can improve the yield and reliability can be provided.

In particular, in the semiconductor device manufacturing method, a semiconductor substrate which awaits operation such as the step of forming a gate oxide film, the step of forming a polysilicon film, and the step of forming a contact hole is preferably stored in the stock/transfer vessel of the present invention. When the semiconductor substrate is stored in the stock/transfer vessel of the present invention during the operation wait time between these steps, an organic substance can be prevented from attaching to the surface of the semiconductor substrate in stock, and the yield and reliability can be improved.

Fourth Embodiment

A silicon wafer used for the manufacture of a semiconductor device was stored for 24 hours in the stock/transfer vessel of the present invention incorporating, as an absorbent, a silicon wafer with a surface having a Si—F bond. When the total amount of organic substances that attached to the silicon wafer was measured by heating/detachable GC-MS, it was less than 0.1×10⁻⁵ g/m².

For comparison, a silicon wafer used for the manufacture of a semiconductor device was stored for 24 hours in the conventional stock/transfer vessel. When the total amount of organic substance attached was measured in the same manner, it was 1.0×10⁻⁵ g/m².

The total amount of organic substances that attached to the silicon wafer stored in the stock/transfer vessel of the present invention is less than 1/10 that attached to the silicon wafer stored in the conventional stock/transfer vessel. This suggests that the stock/transfer vessel of the present invention can clean the air in it.

Fifth Embodiment

Using a silicon wafer as a semiconductor substrate, 100 chips of capacitors each for an n-channel MOS field effect transistor with an area of 30×10⁻⁶ m² were fabricated. The thickness of the gate oxide film was set to 4 nm.

In the process of manufacturing these capacitors, during an operation wait time between the step of forming a gate oxide film and the step of forming a polysilicon film for gate electrode formation, a silicon wafer during the manufacture was stored in the stock/transfer vessel of the present invention incorporating, as an adsorbent, a silicon wafer with a surface having a Si—F bond.

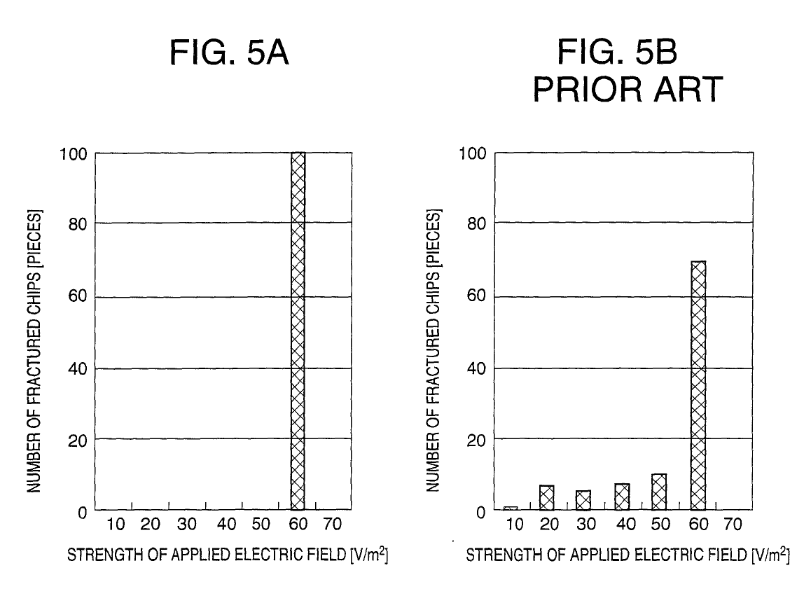

A gate leakage current flowing through the fabricated chips was measured. FIG. 5A is a histogram obtained by measuring converting a gate voltage, obtained when a current of 1.0 A/m² flows, into a field strength. FIG. 5A shows the initial withstand voltage histograms of the gate oxide films.

For comparison, a silicon wafer was stored in the conventional stock/transfer vessel during an operation wait time between the step of forming a gate oxide film and the step of forming a polysilicon film for gate electrode formation, and chips of capacitors each for an n-channel MOS field effect transistor were fabricated with the same conditions as those described above except for the stock condition. FIG. 5B shows the initial withstand voltage histograms of the gate oxide films of the fabricated chips.

As shown in FIG. 5A, when the stock/transfer vessel of the present invention is used, in all of the 100 chips, the strengths of the applied electric fields are concentrated near 60V/m². In contrast to this, as shown in FIG. 5B, when the conventional stock/transfer vessel is used, the strengths of the applied electric fields are 60V/m² in only 70 chips, while those of the remaining 30 chips are equal to or less than that.

An organic substance attaches to the silicon wafers that are stored in the conventional stock/transfer vessel during the operation wait time, and the initial withstand voltages of the gate oxide films of the fabricated chips degrade. In contrast to this, no organic substances attach to the silicon wafers that are stored in the stock/transfer vessel of the present invention. This suggests that degradation in initial withstand voltages of the gate oxide films of the fabricated chips is prevented.

What is claimed is:

1. A semiconductor substrate stock/transfer vessel, which is an openable/closeable sealed vessel used in a semiconductor device manufacturing process and adapted to store or transfer a semiconductor substrate,
wherein said vessel incorporates at least one adsorbent capable of adsorbing an organic substance, and said adsorbent is mounted detachably.

2. A vessel according to claim 1, wherein said vessel incorporates a semiconductor substrate carrier having a plurality of slots each capable of holding one semiconductor substrate, so that a plurality of semiconductor substrates are stored while being held by said semiconductor substrate carrier.

3. A vessel according to claim 1, wherein said adsorbent is a silicon wafer with a surface coated with an adsorbing agent.

4. A vessel according to claim 3, wherein said adsorbing agent is active carbon or an ion-exchange resin.

5. A vessel according to claim 1, wherein said adsorbent is a silicon wafer with a surface having a Si—F bond.

6. A vessel according to claim 2, wherein said adsorbent is mounted in an empty slot of said semiconductor substrate carrier.

7. A vessel according to claim 1, wherein said adsorbent is mounted in a space defined between an inner wall of said stock/transfer vessel and an outer wall of said semiconductor substrate carrier.

8. A vessel according to claim 1, wherein said adsorbent is made of active carbon or an ion-exchange resin.

9. A vessel according to claim 1, wherein said adsorbent is made of active carbon or an ion-exchange resin.

10. A method of manufacturing a semiconductor device wherein a semiconductor substrate is stored in a stock/transfer vessel incorporating at least one adsorbent capable of adsorbing an organic substance during an operation wait time between respective steps of manufacturing said semiconductor device, said adsorbent being mounted detachably.

11. A method according to claim 10, wherein the steps of manufacturing said semiconductor device include the step of forming a gate oxide film, the step of forming a polysilicon film, and the step of forming a contact hole.

12. A method according to claim 10, wherein said vessel incorporates a semiconductor substrate carrier having a plurality of slots each capable of holding one semiconductor substrate, and a plurality of semiconductor substrates are stored while being held by said semiconductor substrate carrier.

13. A method according to claim 10, wherein said adsorbent is a silicon wafer with a surface coated with an adsorbing agent.

14. A method according to claim 13, wherein said adsorbing agent is active carbon or an ion-exchange resin.

15. A method according to claim 10, wherein said adsorbent is a silicon wafer with a surface having a Si—F bond.

16. A method according to claim 12, wherein said adsorbent is mounted in an empty slot of said semiconductor substrate carrier.

17. A method according to claim 10, wherein said adsorbent is mounted in a space defined between an inner wall of said stock/transfer vessel and an outer wall of said semiconductor substrate carrier.

18. A method according to claim 10, wherein said adsorbent is made of active carbon or an ion-exchange resin.
